(19) United States
(12) Patent Application Publication
(10) Pub. No.: US 2020/0388775 A1
(43) Pub. Date: Dec. 10, 2020

(54) DISPLAY PANEL AND DISPLAY DEVICE

(71) Applicant: Wuhan China Star Optoelectronics Semiconductor Display Technology Co., Ltd., Wuhan Hubei (CN)

(72) Inventors: Wei HUANG, Wuhan Hubei (CN); Zhuo ZHANG, Wuhan Hubei (CN)

(73) Assignee: Wuhan China Star Optoeletronics Semiconductor Display Technology Co., Ltd., Wuhan Hubei (CN)

(21) Appl. No.: 16/613,140

(22) PCT Filed: Sep. 10, 2019
(86) PCT No.: PCT/CN2019/105013

§ 371 Date: Nov. 13, 2019

(30) Foreign Application Priority Data
Jun. 6, 2019 (CN) 201910488983.0

(51) Int. Cl. H01L 51/00; H01L 51/52

(52) U.S. Cl. CPC H01L 51/0097; H01L 2251/5338; H01L 51/5237

(57) ABSTRACT

A flexible display panel and a display device are provided. The flexible display panel includes a flexible substrate and a backplate. The backplate includes a bending region and a non-bending region, wherein the bending region includes a plurality of first bending regions and a plurality of second bending regions. The first bending regions and the second bending regions are disposed in a staggered manner, and hardness of the first bending regions is greater than hardness of the second bending regions, which ensures that the backplate has a certain hardness to support the flexible display substrate to relieve stress concentration and reduce a generation rate of cracks.

### FIELD OF INVENTION

The present disclosure relates to the field of display technology, and particularly relates to a flexible display panel and display device.

### BACKGROUND OF INVENTION

With user requirements of using electronic display devices and appearance design requirements continuously getting higher, development of flexible display panels is increasingly receiving attention. In recent years, with rising and continuous development of devices such as wearable smart displays, curved displays, and the like, flexible display panels come into being and have become one of the mainstream trends for development of display industries at present. Flexible display panels have a series of excellent characteristics, such as small sizes, light weight, good bendability, low power consumption, various display modes, easy installation, etc., which can realize diversified applications of display panels, thereby becoming a spotlight of research for all major panel manufacturers.

However, flexible display panels have encountered challenges in designs of bendable structures, especially in backplates (BP), which play a role in supporting and protecting the flexible display panels. For example, if hardness of a flexible bending region on a backplate is insufficient, it will result in inability of the flexible display panel to serve a support function. Furthermore, bending of the flexible display panel easily results in stress concentration on part of the bending region of the flexible display panel, thereby causing problems such as cracks occurring on the flexible display panel, which affect service life of the flexible display panel.

Therefore, it is required to provide a new flexible display panel and a display device to solve technical problems mentioned above.

Therefore, a diffusion sheet structure is necessary to solve the technical problems present in prior art.

### SUMMARY OF INVENTION

The present disclosure provides a flexible display panel and a display device, which solve the technical problem of due to insufficient hardness of a flexible bending region of a backplate causing unable to serve a support function and cracks easily occurring during the flexible display panel being bent.

In order to solve the problems mentioned above, the present disclosure provides technical solutions as follows:

The present disclosure provides a flexible display panel, including:

A flexible substrate.

A backplate, which is disposed on a back surface of the flexible substrate. The backplate includes a bending region and a non-bending region connected to the bending region.

Furthermore, the bending region includes a plurality of first bending regions and a plurality of second bending regions. A material of the first bending regions is metal. A material of the second bending regions is elastic material. The plurality of first bending regions and the plurality of second bending regions are disposed in a staggered manner, and a hardness of the first bending regions is greater than a hardness of the second bending regions.

In the flexible display panel provided by an embodiment of the present disclosure, when the bending region is in an expanded state, a dimension of the second bending regions on a first direction sequentially increases along a second direction. Furthermore, the first direction is an expanded direction of the bending region, and the second direction is perpendicular to the first direction.

In the flexible display panel provided by an embodiment of the present disclosure, a shape of a cross section of the second bending region between two of the first bending regions is an inverted isosceles trapezoidal shape, and a shape of a cross section of the first bending region between two of the second bending regions is an isosceles trapezoidal shape.

In the flexible display panel provided by an embodiment of the present disclosure, a shape of a cross section of the first bending region located on an edge of the bending region is a right trapezoidal shape, and a shape of a cross section of second bending region located on an edge of the bending region is an inverted right trapezoidal shape.

In the flexible display panel provided by an embodiment of the present disclosure, a material of the second bending regions is rubber.

In the flexible display panel provided by an embodiment of the present disclosure, an area of a plurality of cross sections of the first bending regions is equal to an area of a plurality of cross sections of the second bending regions.

In the flexible display panel provided by an embodiment of the present disclosure, the area of the cross sections of the first bending regions is 20% to 40% of an area of a cross section of the bending region.

An embodiment of the present disclosure provides a flexible display panel, including:

A flexible substrate.

A backplate, which is disposed on a back surface of the flexible substrate. The backplate includes a bending region and a non-bending region connected to the bending region.

Furthermore, the bending region includes a plurality of first bending regions and a plurality of second bending regions. The plurality of first bending regions and the plurality of second bending regions are disposed in a staggered manner, and a hardness of the first bending regions is greater than a hardness of the second bending regions.

In the flexible display panel provided by an embodiment of the present disclosure, when the bending region is in an expanded state, a dimension of the second bending regions on a first direction sequentially increases along a second direction, wherein the first direction is an expanded direction of the bending region, and the second direction is perpendicular to the first direction.

In the flexible display panel provided by an embodiment of the present disclosure, a shape of a cross section of the second bending region between two of the first bending regions is an inverted isosceles trapezoidal shape, and a shape of a cross section of the first bending region between two of the second bending regions is an isosceles trapezoidal shape.

In the flexible display panel provided by an embodiment of the present disclosure, a shape of a cross section of the first bending region located on an edge of the bending region is a right trapezoidal shape, and a shape of a cross section of second bending region located on an edge of the bending region is an inverted right trapezoidal shape.

In the flexible display panel provided by an embodiment of the present disclosure, a material of the first bending regions is metal.

In the flexible display panel provided by an embodiment of the present disclosure, a material of the second bending regions is elastic material.

In the flexible display panel provided by an embodiment of the present disclosure, a material of the second bending regions is rubber.

In the flexible display panel provided by an embodiment of the present disclosure, an area of a plurality of cross sections of the first bending regions is equal to an area of a plurality of cross sections of the second bending regions.

In the flexible display panel provided by an embodiment of the present disclosure, the area of the cross sections of the first bending regions is 20% to 40% of an area of a cross section of the bending region.

An embodiment of the present disclosure provides a display device includes the flexible display panel mentioned above.

The beneficial effect of the present disclosure is that the flexible display panel and the display device provided by the present disclosure ensure the bending region of the backplate has certain hardness to support the flexible display panel by adopting the structure of the plurality of first bending regions and the plurality of second bending regions disposed in a staggered manner on the bending region of the backplate, and the hardness of the first bending regions is greater than the hardness of the second bending regions. Meanwhile, the material of the second bending regions is the elastic material, which effectively relieves stress concentration, thereby reducing the generation rate of cracks on the flexible display panel to improve service life and performances of the flexible display panel.

### DESCRIPTION OF DRAWINGS

To more clearly illustrate embodiments or the technical solutions of the present disclosure, the accompanying figures of the present disclosure required for illustrating embodiments or the technical solutions of the present disclosure will be described in brief. Obviously, the accompanying figures described below are only part of the embodiments of the present disclosure, from which those skilled in the art can derive further figures without making any inventive efforts.

FIG. 1 is a structural schematic diagram of a cross section of a flexible display panel provided by a first embodiment of the present disclosure.

FIG. 2 is a structural schematic diagram of an expanded state of a backplate of the flexible display panel provided by the first embodiment of the present disclosure.

FIG. 3 is a structural schematic diagram of an expanded state of a bending region of the flexible display panel provided by the first embodiment of the present disclosure.

FIG. 4 is a structural schematic diagram of a bending state of the bending region of the flexible display panel provided by the first embodiment of the present disclosure.

FIG. 5 is a structural schematic diagram of the flexible display panel provided by a second embodiment of the present disclosure.

### DETAILED DESCRIPTION OF PREFERRED EMBODIMENTS

The descriptions of embodiments below refer to accompanying drawings in order to illustrate certain embodiments which the present disclosure can implement. The directional terms of which the present disclosure mentions, for example, “top”, “bottom”, “upper”, “lower”, “front”, “rear”, “left”, “right”, “inside”, “outside”, “side”, etc., are only referring to directions of the accompanying figures. Therefore, the adopted directional terms are used to describe and understand the present disclosure, but the present disclosure is not limited thereto. In the figures, units with similar structures are indicated by the same reference numerals.

The present disclosure is aimed at a flexible display panel and a display device of prior art, since hardness of backplate bending region is insufficient, the flexible display panel cannot serve a support function, and cracks easily occur when the flexible display panel is bent. The present disclosure can solve the defect.

### The First Embodiment

Illustrated in FIG. 1, is a structural schematic diagram of a cross section of a flexible display panel 10 provided by an embodiment of the present disclosure. The flexible display panel 10 includes a flexible substrate 200 and a backplate 100 disposed on a back surface of the flexible substrate 200. The backplate 100 includes a bending region 101 and a non-bending region 102 connected to the bending region 101. The bending region 101 is located on a middle of the non-bending region 102. Furthermore, there is a structure distributed in a staggered manner in the bending region 101. It should be noted, that the flexible display panel 10 can be an organic light emitting diode (OLED) display panel, which is easy for realizing bending. However, it is only one situation of this embodiment, in another selectable embodiment, the flexible display panel 10 may also be another display panel, and details will not be mentioned herein.

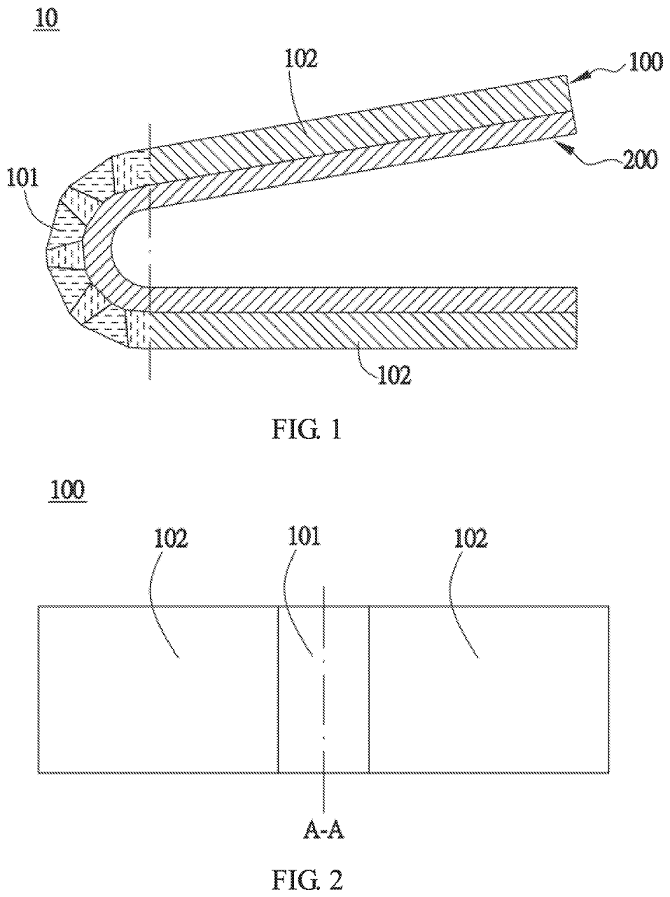

Continuing, refer to FIG. 2, FIG. 2 is a structural schematic diagram of an expanded state of the backplate 100 of the flexible display panel 10 provided by the embodiment of the present disclosure. The backplate 100 is bent along a bending axis A-A located in the bending region 101, that is, the non-bending region 102 located on both sides of the bending region 101 encircles the bending axis A-A to be bent. A large stress is generated when the bending region 101 is bent, and a phenomenon of stress concentration easily occurs on metal traces located in the bending region 101, thereby easily causing the metal traces to fracture.

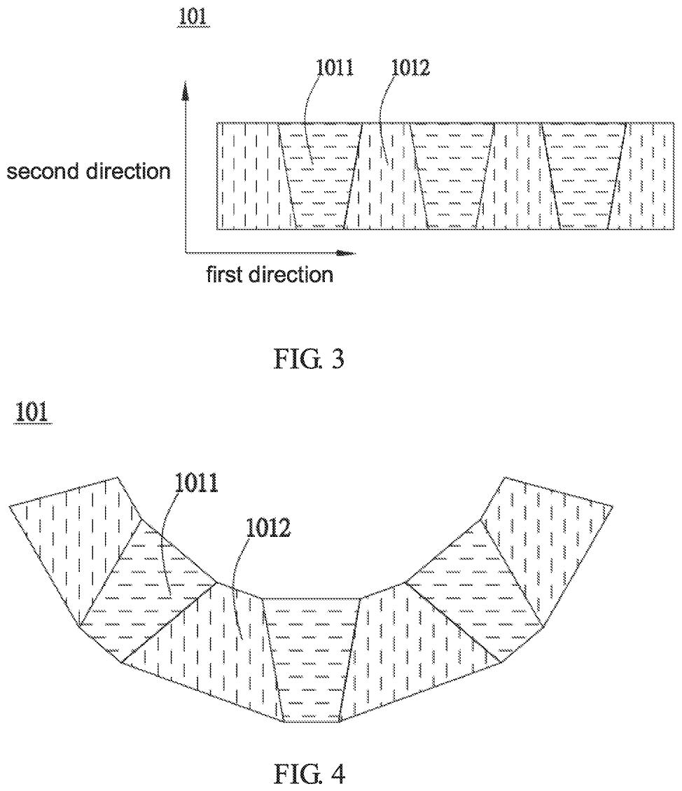

Illustrated in FIG. 3 is a structural schematic diagram of an expanded state of the bending region 101 of the flexible display panel 100 provided by the embodiment of the present disclosure. The bending region 101 of the backplate 100 includes a plurality of first bending regions 1011 and a plurality of second bending regions 1012. The plurality of first bending regions 1011 and the plurality of second bending regions 1012 are disposed in a staggered manner, and cross sections of the plurality of first bending regions 1011 and the plurality of second bending regions 1012 are fully arranged on a cross section of the bending region 101.

Furthermore, a hardness of the first bending regions 1011 is greater than a hardness of the second bending regions 1012. Specifically, a material of the first bending regions is metal material, such as iron, silver, or an alloy material, which makes the bending region 101 have a certain hardness to support and protect the flexible substrate 200 to prevent the flexible substrate 200 from being damaged. Of course, in another selectable embodiment, the first bending regions 1011 can be of another material, and this embodiment is not specifically limited thereto. Preferably, in order to ensure that the bending region 101 has a sufficient hardness, an area of the cross sections of the first bending regions 1011 is generally 20% to 40% of an area of the cross section of the bending region 101.

Furthermore, an elastic material can be selected as a material of the second bending regions 1012, which makes the second bending regions 1012 have good extendibility. Preferably, the material of the second bending regions 1012 is a rubber material. Because the rubber material is a high elastic polymer material having reversible deformation, it can produce greater deformation under effect of a small external force, and can br restored to its original state after the external force is removed. Of course, in another selectable embodiment, the second bending regions 1012 can be other elastic materials, and this embodiment is not specifically limited thereto.

Illustrated in FIG. 4 is a structural schematic diagram of a bending state of the bending region 101 of the flexible display panel 100 provided by the embodiment of the present disclosure. When the bending region 101 is bent, because the hardness of the first bending regions 1011 is greater, deformation is basically not generated on the first bending regions 1011. However, deformation occurs on the second bending regions 1012, and an internal surface and an external surface of the bending region 101 receive different levels of stresses.

In order to generate deformations of different levels on the internal surface and the external surface of the bending region 101, a dimension of the second bending regions 1012 on a first direction can be sequentially increased along a second direction. Furthermore, the first direction is an expanded direction of the bending region 101, and the second direction is perpendicular to the first direction.

It can be understood that the second direction is perpendicular to the internal surface and the external surface of the bending region 101, so that the deformation of the second bending regions 1012 gradually increases along the second direction. Furthermore, the deformation of the second bending regions 1012 is largest on the internal surface of the bending region 101. The deformation of the second bending regions 1012 is smallest on the external surface of the bending region 101 to prevent cracks occurring on the bending region 101, thereby reducing a generation rate of the cracks on the flexible display panel 10 to improve service life and performance of the flexible display panel 10. Furthermore, when the bending region 101 transits form the bending state to the expanded state, the second bending regions 1012 can recover to the original shape and have good flexible performance.

Preferably, the dimension of the second bending regions 1012 on the first direction evenly increases along the second direction, which increases the deformation of the second bending regions 1012 along the second direction, and is advantageous to evenly distributing the stress of the bending region 101 to relieve the local stress concentration.

Preferably, a shape of a cross section of the second bending region 1012 between two of the first bending regions 1011 is an inverted isosceles trapezoidal shape, and a shape of a cross section of the first bending region 1011 between two of the second bending regions 1012 is an isosceles trapezoidal shape. Because an isosceles trapezoidal shape has a characteristic of good symmetry, it can evenly distribute the stress of the bending region 101 to relieve the local stress concentration. Meanwhile, because a shape of the bending region 101 is generally a rectangular shape, if the first bending region 1011 is located on an edge of the bending region 101, the shape of the cross section of the first bending region 1011 located on the edge of the bending region 101 is a right trapezoidal shape; if the second bending region 1012 is located on an edge of the bending region 101, the shape of the cross section of the second bending region 1012 located on the edge of the bending region 101 is an inverted right trapezoidal shape. Of course, in another selectable embodiment, the first bending regions 1011 and the second bending regions 1012 can be other shapes, and this embodiment is not specifically limited thereto.

Preferably, areas of the plurality of cross sections of the first bending regions 1011 are same, and areas of the plurality of cross sections of the second bending regions 1012 are same. On one hand, the hardness of the bending region 101 can be distributed evenly, thereby maintaining stability of the flexible display panel 10; on the other hand, it can evenly relieve the stress level endured by the bending region 101, so that the phenomenon of stress concentration can be more evenly distributed, thereby further reducing the generation rate of cracks on the flexible display panel 10.

Furthermore, a number of the first bending regions 1011 and a number of the second bending regions 1012 are not limited. However, in order to make an alleviating effect of the stress on the bending region 101 more significant, the number of the first bending regions 1011 and the number of the second bending regions 1012 can be maximized according to a specific situation, that is, disposing the distribution of the first bending regions 1011 and the second bending regions 1012 in the bending region 101 to be more concentrated to meet the requirement.

### The Second Embodiment

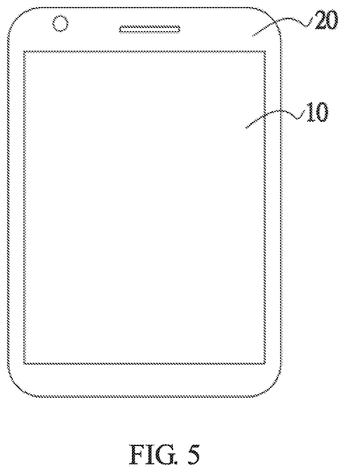

As illustrated in FIG. 5, the present disclosure further provides a display device 20. The display device 20 includes the flexible display panel 10 provided by the first embodiment. The display device 20 can be a display device, such as a television, a mobile phone, a laptop, a wearable smart display device, and the like, and also can be another display device. The display device 20 includes the technical effect of the flexible display panel 10, and details will not be mentioned herein.

The beneficial effects is that the flexible display panel and the display device provided by the present disclosure ensures the bending region of the backplate has certain hardness to support the flexible display panel by adopting the structure of the plurality of first bending regions and the plurality of second bending regions disposed in a staggered manner on the bending region of the backplate, and the hardness of the first bending regions is greater than the hardness of the second bending regions. Meanwhile, the material of the second bending regions is the elastic material, which effectively relieves stress concentration, thereby reducing the generation rate of cracks on the flexible display panel to improve service life and performances of the flexible display panel.

In summary, although the present disclosure has disclosed the preferred embodiments as above, the above-mentioned preferred embodiments are not to limit to the present disclosure. A person skilled in the art can make any change and modification, therefore the scope of protection of the present disclosure is subject to the scope defined by the claims.

What is claimed is:

1. A flexible display panel, comprising:
a flexible substrate; and
a backplate disposed on a back surface of the flexible substrate, the backplate comprising a bending region and a non-bending region connected to the bending region;
wherein the bending region comprises a plurality of first bending regions and a plurality of second bending regions, a material of the first bending regions is metal, a material of the second bending regions is elastic material, the plurality of first bending regions and the plurality of second bending regions are disposed in a staggered manner, and a hardness of the first bending regions is greater than a hardness of the second bending regions.

2. The flexible display panel as claimed in claim 1, wherein when the bending region is in an expanded state, a dimension of the second bending regions on a first direction sequentially increases along a second direction, wherein the first direction is an expanded direction of the bending region, and the second direction is perpendicular to the first direction.

3. The flexible display panel as claimed in claim 2, wherein a shape of a cross section of the second bending region between two of the first bending regions is an inverted isosceles trapezoidal shape, and a shape of a cross section of the first bending region between two of the second bending regions is an isosceles trapezoidal shape.

4. The flexible display panel as claimed in claim 2, wherein a shape of a cross section of the first bending region located on an edge of the bending region is a right trapezoidal shape, and a shape of a cross section of the second bending region located on the edge of the bending region is an inverted right trapezoidal shape.

5. The flexible display panel as claimed in claim 1, wherein the material of the second bending regions is rubber.

6. The flexible display panel as claimed in claim 1, wherein an area of a plurality of cross sections of the first bending regions is equal to an area of a plurality of cross sections of the second bending regions.

7. The flexible display panel as claimed in claim 6, wherein the area of the cross sections of the first bending regions is 20% to 40% of an area of a cross section of the bending region.

8. A flexible display panel, comprising:
a flexible substrate; and
a backplate disposed on a back surface of the flexible substrate, the backplate comprising a bending region and a non-bending region connected to the bending region;
wherein, the bending region comprises a plurality of first bending regions and a plurality of second bending regions, the plurality of first bending regions and the plurality of second bending regions are disposed in a staggered manner, and a hardness of the first bending regions is greater than a hardness of the second bending regions.

9. The flexible display panel as claimed in claim 8, wherein when the bending region is in an expanded state, a dimension of the second bending regions on a first direction sequentially increases along a second direction, wherein the first direction is an expanded direction of the bending region, and the second direction is perpendicular to the first direction.

10. The flexible display panel as claimed in claim 9, wherein a shape of a cross section of the second bending region between two of the first bending regions is an inverted isosceles trapezoidal shape, and a shape of a cross section of the first bending region between two of the second bending regions is an isosceles trapezoidal shape.

11. The flexible display panel as claimed in claim 9, wherein a shape of a cross section of the first bending region located on an edge of the bending region is a right trapezoidal shape, and a shape of a cross section of the second bending region located on the edge of the bending region is an inverted right trapezoidal shape.

12. The flexible display panel as claimed in claim 8, wherein a material of the first bending regions is metal.

13. The flexible display panel as claimed in claim 8, wherein a material of the second bending regions is elastic material.

14. The flexible display panel as claimed in claim 13, wherein the material of the second bending regions is rubber.

15. The flexible display panel as claimed in claim 8, wherein an area of a plurality of cross sections of the first bending regions is equal to an area of a plurality of cross sections of the second bending regions.

16. The flexible display panel as claimed in claim 15, wherein the area of the cross sections of the first bending regions is 20% to 40% of an area of a cross section of the bending region.

17. A display device, comprising the flexible display panel as claimed in claim 8.
